(19) United States
(12) Patent Application Publication
(10) Pub. No.: US 2025/0298435 A1
(43) Pub. Date: Sep. 25, 2025

(54) Display for Wearable Computing Devices Having a Three-Dimensional Cover

(71) Applicant: Google LLC, Mountain View, CA (US)

(72) Inventors: Choongho Lee, San Diego, CA (US); James Edward Stewart, San Mateo, CA (US); Jens Mitchell Nielsen, San Francisco, CA (US); David Alexander Kalinowski, San Francisco, CA (US); Junyong Park, San Francisco, CA (US); Triton Hurd, Encinitas, CA (US)

(21) Appl. No.: 18/716,725

(22) PCT Filed: Dec. 6, 2021
(86) PCT No.: PCT/US2021/061954

§ 371 Date: Jun. 5, 2024

(51) Int. Cl. G06F 1/16; H10K 59/131; H10K 59/40; H10K 59/65

(52) U.S. Cl. CPC G06F 1/163; G06F 1/1637; H10K 59/131; H10K 59/40; H10K 59/65

(57) ABSTRACT

A display for an electronic device is provided. The display includes a first display area having a first plurality of pixels. The display includes a connecting area extending from a periphery of the first display area. The display includes a second display area having a second plurality of pixels. The second display area includes a first portion and a second portion. The first portion extends from the connecting area and around a first portion of the periphery of the first display area. The second portion extends from the connecting area and around a second portion of the periphery of the first display area. The second portion of the periphery is different than the first portion of the periphery of the first display area.

### FIELD

The present disclosure relates generally to displays for wearable computing devices. More particularly, the present disclosure relates to displays for wearable computing devices having a three-dimensional cover.

### BACKGROUND

Wearable computing devices (e.g., wrist watches) can include a display to display content (e.g., time, date, etc.) to a user. Wearable computing devices can gather data regarding activities performed by the user, or regarding the user's physiological state. Such data may include data representative of the ambient environment around the user or the user's interaction with the environment. For example, the data can include motion data regarding the user's movements and/or physiological data obtained by measuring various physiological characteristics of the user, such as heart rate, perspiration levels, and the like.

### SUMMARY

Aspects and advantages of embodiments of the present disclosure will be set forth in part in the following description, or can be learned from the description, or can be learned through practice of the embodiments.

In one aspect, a display is provided. The display includes a first display area having a first plurality of pixels. The display includes a connecting area extending from a periphery of the first display area. The display includes a second display area having a second plurality of pixels. The second display area includes a first portion and a second portion. The first portion extends from the connecting area and around a first portion of the periphery of the first display area. The second portion extends from the connecting area and around a second portion of the periphery of the first display area. The second portion of the periphery is different than the first portion of the periphery of the first display area.

In some implementations, a total number of pixels included in the first plurality of pixels is different than a total number of pixels included in the second plurality of pixels.

In some implementations, a first gap is defined between the first portion of the second display area and the first portion of the periphery of the first display area. In addition, a second gap is defined between the second portion of the second display area and the second portion of the periphery of the first display area.

In some implementations, the display includes a first plurality of conductors and a second plurality of conductors. Each conductor of the first plurality of conductors is electrically coupled to a corresponding pixel of the first plurality of pixels. Each conductor of the second plurality of pixels is electrically coupled to a corresponding pixel of the second plurality of pixels. In some implementations, each conductor of the second plurality of conductors extends from the first display area to the second display area via the connecting area.

In some implementations, the display includes a display driver circuit. The display driver circuit includes a first memory buffer and a second memory buffer. The first memory buffer is communicatively coupled to each of the first plurality of pixels via a corresponding conductor of the first plurality of pixels. The second memory buffer is communicatively coupled to each of the second plurality of pixels via a corresponding conductor of the second plurality of pixels. In some implementations, a gap is defined between an end of the first portion of the second display area and an end of the second portion of the second display area.

In another aspect, a wearable computing device is provided. The wearable computing device includes a housing and a three-dimensional cover positioned on the housing. The three-dimensional cover includes a transparent material (e.g., a glass material) and defines an internal volume. The wearable computing device further includes a display disposed within the internal volume defined by the three-dimensional cover. The display includes a first connecting area extending from a periphery of the first display area. The display includes a second display area having a second plurality of pixels. The second display area includes a first portion and a second portion. The first portion extends from the first connecting area and around a first portion of the periphery of the first display area. The second portion extends from the first connecting area and around a second portion of the periphery of the second display area. The second portion of the periphery of the first display area is different than the first portion of the periphery of the first display area.

In some implementations, the first portion of the second display area and the second portion of the second display area are each coupled to a curved portion of an interior surface of the three-dimensional cover. For instance, in some implementations, at least one of the first portion of the second display area or the second portion of the second display area is laminated to the curved portion of the interior surface of the three-dimensional cover. In some implementations, the display includes an organic light emitting diode (OLED) display.

In some implementations, a first gap is defined between the first display area and the first portion of the second display area. Furthermore, a second gap is defined between the first display area and the second portion of the second display area.

In some implementations, the display includes a second connecting area extending from the periphery of the first display area. The second connecting area is spaced apart from the first connecting area along the periphery of the first display area. The display further includes a third display area having a third plurality of pixels. The third display area includes a first portion extending from the second connecting area and around a third portion of the periphery of the first display area. The third display area further includes a second portion extending from the second connecting area and around a fourth portion of the periphery of the first display area.

In some implementations, the display includes a first plurality of conductors and a second plurality of conductors. Each conductor of the first plurality of conductors is electrically coupled to a corresponding pixel of the first plurality of pixels. Each conductor of the second plurality of pixels is electrically coupled to a corresponding pixel of the second plurality of pixels. In some implementations, each conductor of the second plurality of conductors extends from the first display area to the second display area via the first connecting area.

In some implementations, the display includes a display driver circuit. The display driver circuit includes a first memory buffer and a second memory buffer. The first memory buffer is communicatively coupled to each of the first plurality of pixels via a corresponding conductor of the first plurality of pixels. The second memory buffer is communicatively coupled to each of the second plurality of pixels via a corresponding conductor of the second plurality of pixels. In some implementations, a gap is defined between an end of the first portion of the second display area and an end of the second portion of the second display area.

In some implementations, the second display area of the display is configured as a touch-screen display. In some implementations, the wearable computing device further includes an image sensor positioned within the internal volume of the three-dimensional cover such that the image sensor is positioned behind the second display area of the display.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts a wearable computing device according to some implementations of the present disclosure.

FIG. 2 depicts a cross-sectional view of a wearable computing device according to some implementations of the present disclosure.

FIG. 3 depicts an exploded view of a wearable computing device according to some implementations of the present disclosure.

FIG. 4 depicts a perspective view of a three-dimensional cover for a wearable computing device according to some implementations of the present disclosure.

FIG. 5 depicts a bottom view of the three-dimensional cover of FIG. 4 according to some implementations of the present disclosure.

FIG. 6 depicts a perspective view of a display for a wearable computing device having a three-dimensional cover according to some implementations of the present disclosure.

FIG. 7 depicts a cross-sectional view of the display of FIG. 6 according to some implementations of the present disclosure.

FIG. 8 depicts a top view of the three-dimensional cover of FIG. 4 with the display of FIG. 6 positioned within the internal volume thereof according to some implementations of the present disclosure.

FIG. 9 depicts a side view of the three-dimensional cover of FIG. 4 with the display of FIG. 6 positioned within the internal volume thereof according to some implementations of the present disclosure.

FIG. 10 depicts a schematic of electrical connections for pixels of the display of FIG. 6 according to some implementations of the present disclosure.

FIG. 11 depicts a perspective view of another display for a wearable computing device having a three-dimensional cover according to some implementations of the present disclosure.

FIG. 12 depicts a cross-sectional view of the display of FIG. 11 according to some implementations of the present disclosure.

FIG. 13 depicts a top view of the three-dimensional cover of FIG. 4 with the display of FIG. 11 positioned within the internal volume thereof according to some implementations of the present disclosure.

FIG. 14 depicts a side view of the three-dimensional cover of FIG. 4 with the display of FIG. 11 positioned within the internal volume thereof according to some implementations of the present disclosure.

FIG. 15 depicts another side view of the three-dimensional cover of FIG. 4 with the display of FIG. 11 positioned within the internal volume thereof according to some implementations of the present disclosure.

FIG. 16 depicts a schematic of electrical connections for pixels of the display of FIG. 11 according to some implementations of the present disclosure.

FIG. 17 depicts an image sensor positioned within an internal volume of a three-dimensional cover of a wearable computing device according to some implementations of the present disclosure.

### DETAILED DESCRIPTION

Reference now will be made in detail to embodiments of the present disclosure, one or more examples of which are illustrated in the drawings. Each example is provided by way of explanation of the present disclosure, not limitation of the present disclosure. In fact, it will be apparent to those skilled in the art that various modifications and variations can be made in the present disclosure without departing from the scope or spirit of the disclosure. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to a wearable computing device that can be worn, for instance, on a user's wrist. The wearable computing device can include a housing and a display. The display can be configured to display content for viewing by the user. The wearable computing device can further include a cover positioned on the housing such that the cover is positioned over the display. In this manner, the cover can protect the display from being damaged (e.g., scratched). Furthermore, the cover can include a transparent material (e.g., glass). In this manner, the user can view the content on the display through the cover.

Example aspects of the present disclosure are directed to a display (e.g., organic light emitting diode (OLED) display) that can be used in wearable computing devices having a three-dimensional cover defining an internal volume. The display can include a first display area (e.g., main display area) and a second display area (e.g. secondary display area). It should be understood that the first display area and the second display area can each include a plurality of pixels.

The first display area can be coupled (e.g. laminated) to an interior surface of a first portion (e.g., flat portion) of the three-dimensional cover. In this manner, the first display area can display content for viewing through the first portion of the three-dimensional cover. Additionally, the second display area can be coupled (e.g., laminated) to an interior surface of a second portion (e.g., curved portion) of the three-dimensional cover. In this manner, the second display area of the display can provide content for viewing by the user of the wearable computing device through the second portion (e.g., curved portion) of the three-dimensional cover glass.

The display can include a connecting area (e.g., an area having no pixels) extending from a periphery of the first display area to the second display area. Furthermore, the second display area can extend from the connecting area. For instance, the second display area can include a first portion extending from the connecting area in a first direction (e.g., clockwise) and a second portion extending from the connecting area in a second direction (e.g., counterclockwise) that is opposite the first direction. In this manner, the first portion of the second display area can extend around a first portion of the periphery of the first display area, whereas the second portion of the second display area can extend around a second portion of the periphery of the first display area. It should be understood that the second portion of the periphery of the first display area is different (e.g., does not overlap) than the second portion of the periphery of the first display area. In this manner, the first portion of the second display area and the second portion of the second display area do not overlap.

In some implementations, the connecting area is flexible relative to the first display area. For instance, the connecting area of the display can be bent downward relative to the first display area. In this manner, the second display area can be bent relative to the first display area to position the second display area for coupling (e.g., laminating) the second display area to the curved interior surface of the three-dimensional cover. In alternative implementations, the connecting area can be curved. For instance, the connecting area can extend from the first display area along two directions (e.g., radial direction and vertical direction).

The display can include a first plurality of conductors and a second plurality of conductors. Each conductor of the first plurality of conductors can be electrically coupled to a corresponding pixel of the plurality of pixels included in the first display area. Furthermore, each conductor of the second plurality of conductors can be electrically coupled to a corresponding pixel of the plurality of pixels included in the second display area. In this manner, the first display area and the second display area can be controlled independently of one another.

The display can include a display driver circuit having a dedicated memory buffer for each of the display areas (e.g., first display area, second display area). For instance, the display can include a first memory buffer and a second memory buffer. The first memory buffer can be communicatively coupled to each of the pixels of the first display area via a corresponding conductor of the first plurality of conductors. The second memory buffer can be communicatively coupled to each of the pixels of the second display area via a corresponding conductor of the second plurality of conductors. In this manner, the first display area and the second display area can be independently controlled. For instance, in some implementations, the second display area can be controlled to function as an always on display (AOD).

A wearable computing device according to example aspects of the present disclosure can provide numerous technical effects and benefits. For instance, the first display area of the display and the second display area of the display allows the display to accommodate the shape of a three-dimensional cover of a wearable computing device. For instance, the first display area can be coupled to a flat portion of an interior surface of the three-dimensional cover, whereas the second display area can wrap around a curved portion of the interior surface of the three-dimensional cover. In this manner, the first display area can provide content for viewing through the flat portion of the three-dimensional cover, whereas the second display area can provide content for viewing through the curved portion of the three-dimensional cover. Furthermore, since the display includes dedicated conductors and memory buffers for the first display area and the second display area, the display areas (e.g., first display area, second display area) can be controlled independently of one another.

Still further, in some implementations, the second display area can be configured as a touchscreen thereby eliminating the need for separate input devices (e.g. press-button). The touchscreen functionality of the second display area can allow the user to provide different touch inputs (e.g., scroll, button press). For example, the touchscreen of the second display area can function as a dial for the user to provide input (e.g., scroll) associated with controlling operation of a device (e.g., thermostat) that is communicatively coupled to the wearable computing device. In this manner, the touchscreen of the second display area can allow the user finer control of the external device. As another example, different portions of the second display area can be touched (e.g., pressed) by the user to start/stop a clock associated with an exercise application running on the wearable computing device. Furthermore, the portions of the second display area that can be touched by the user to start/stop the clock can be in different locations depending on which wrist (e.g., left wrist, right right) the user wears the wearable computing device. In this manner, the portions of the second display area that can be touched to control the clock of the exercise application can be accessible regardless of which wrist the user wears the wearable computing device.

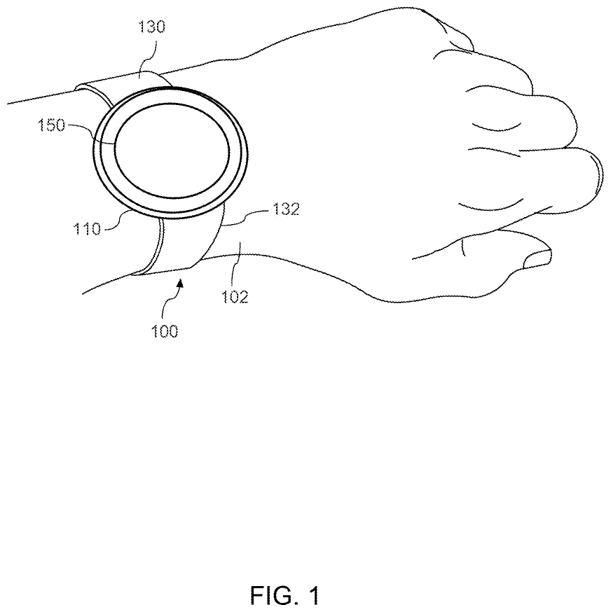

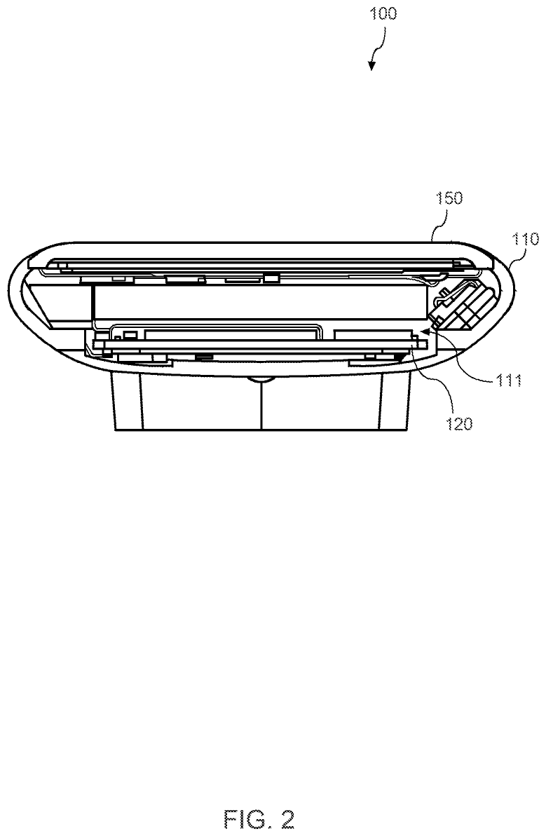

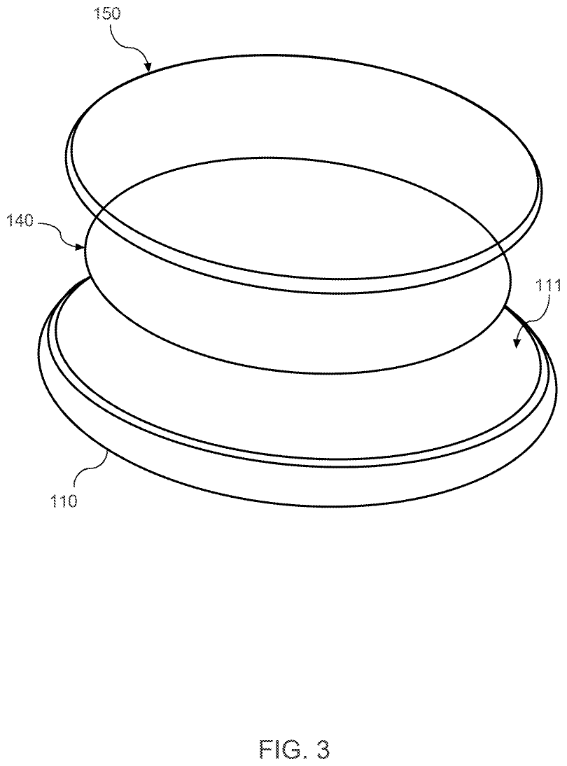

Referring now to the FIGS. FIGS. 1 through 3 depict a wearable computing device 100 according to some implementations of the present disclosure. As shown, the wearable computing device 100 can be worn, for instance, on an arm 102 (e.g., wrist) of a user. For instance, the wearable computing device 100 can include a housing 110. The housing 110 can define a cavity 111 in which one or more electronic components (e.g., disposed on printed circuit boards) are disposed. For instance, the wearable computing device 100 can include a printed circuit board 120 disposed within the cavity 111. Furthermore, one or more electronic components can be disposed on the printed circuit board 120. The wearable computing device 100 can further include a battery (not shown) that is disposed within the cavity 111 defined by the housing 110.

The wearable computing device 100 can include a first band 130 and a second band 132. As shown, the first band 130 can be coupled to the housing 110 at a first location thereon. Conversely, the second band 132 can be coupled to the housing 110 at a second location thereon. Furthermore, the first band 130 and the second band 132 can be coupled to one another to secure the housing 110 to the arm 102 of the user.

In some implementations, the first band 130 can include a buckle or clasp (not shown). Additionally, the second band 132 can include a plurality of apertures (not shown) spaced apart from one another along a length of the second band 132. In such implementations, a prong of the buckle associated with the first band 130 can extend through one of the plurality of openings defined by the second band 132 to couple the first band 130 to the second band 132.

It should be appreciated that the first band 130 can be coupled to the second band 132 using any suitable type of fastener. For instance, in some implementations, the first band 130 and the second band 132 can include a magnet. In such implementations, the first band 130 and the second band 132 can be magnetically coupled to one another to secure the housing 110 to the arm 102 of the user.

The wearable computing device 100 can include a display 140 configured to display content (e.g., time, date, biometric, notifications, etc.) for viewing by the user. For instance, the display 140 can include a plurality of pixels. In some implementations, the display 140 can include an organic light emitting diode (OLED) display. It should be understood, however, that the display 140 can include any suitable type of display.

The wearable computing device 100 can include a cover 150 positioned on the housing 110 so that the cover 150 is positioned on top of the display 140. In this manner, the cover 150 can protect the display 140 from being scratched. In some implementations, the wearable computing device 100 can include a seal (not shown) positioned between the housing 110 and the cover 150. For instance, a first surface of the seal can contact the housing 110 and a second surface of the seal can contact the cover 150. In this manner, the seal between the housing 110 and the cover 150 can prevent a liquid (e.g., water) from entering the cavity 111 defined by the housing 110.

It should be understood that the cover 150 can be optically transparent so that the user can view information being displayed on the display 140. For instance, in some implementations, the cover 150 can include a glass material. It should be understood, however, that the cover 150 can include any suitable optically transparent material.

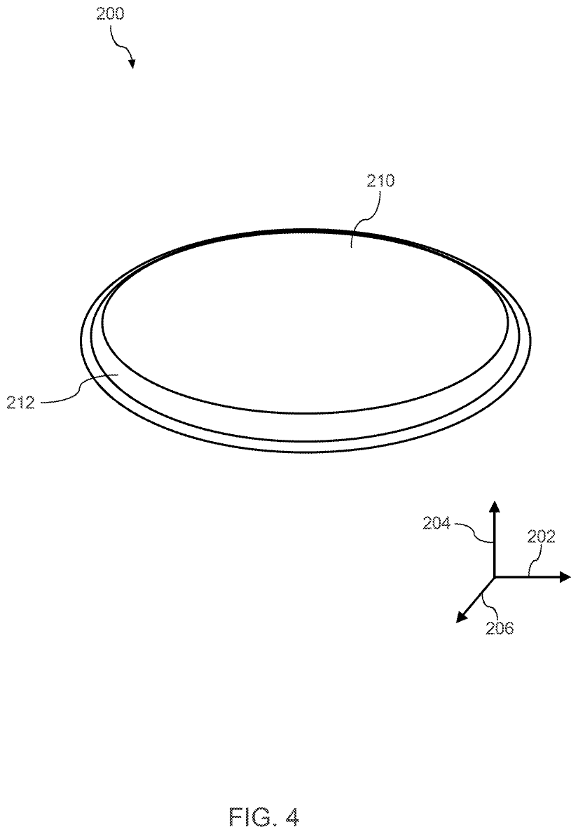

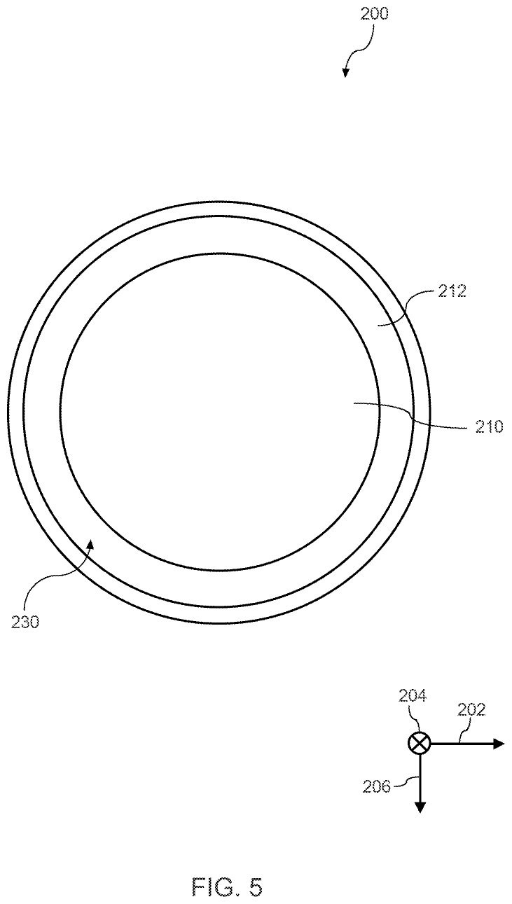

Referring now to FIGS. 4 and 5, a three-dimensional cover 200 for a wearable computing device is provided. The three-dimensional cover 200 defines an x-axis 202, a y-axis and a z-axis 206. It should be understood that the x-axis 202, the y-axis 204, and the z-axis 206 are substantially perpendicular (e.g., less than a 15 degree difference, less than a 10 degree difference, less than a 5 degree difference, less than a 1 degree difference, etc.) to one another. It should also be understood that wearable computing device 100 discussed above with reference to FIGS. 1 through 3 can include the three-dimensional cover 200. For instance, the cover 150 discussed above with reference to FIGS. 1 through 3 can include the three-dimensional cover 200. Details of the three-dimensional cover 200 will now be discussed.

The three-dimensional cover 200 can include a first portion 210 and a second portion 212. The first portion 210 of the three-dimensional cover 200 can extend along the x-axis 202 and the z-axis 206. In this manner, the first portion 210 can be substantially flat. The second portion 212 of the three-dimensional cover 200 can extend from the first portion 210 of the three-dimensional cover 200 along the y-axis 204. The second portion 212 can have an annular shape. Furthermore, the second portion 212 of the three-dimensional cover 200 can extend around a periphery of the first portion 210 of the three-dimensional cover 200. In this manner, the first portion 210 of the three-dimensional cover 200 and the second portion 212 of the three-dimensional cover 200 can collectively define an internal volume 230 in which a display of a wearable computing device can be positioned. In some implementations, the three-dimensional cover 200 can have a frustoconical shape.

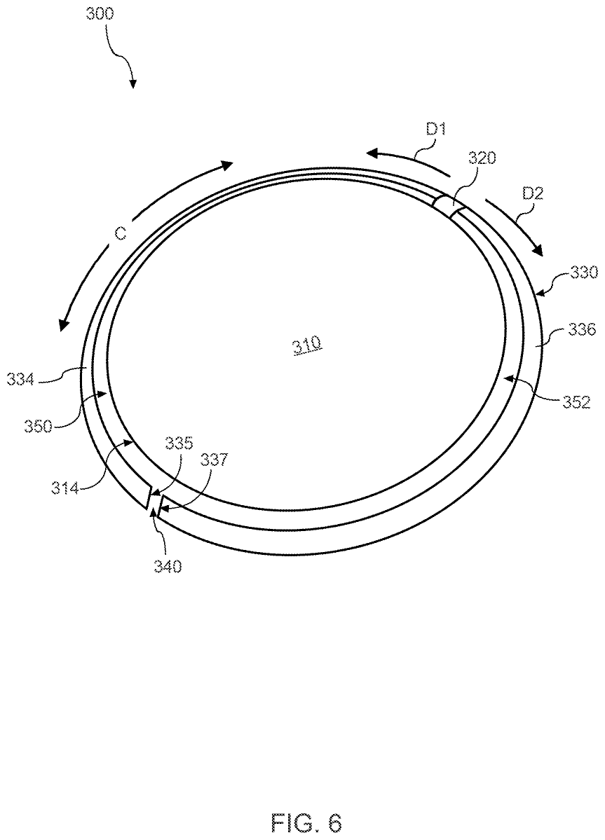

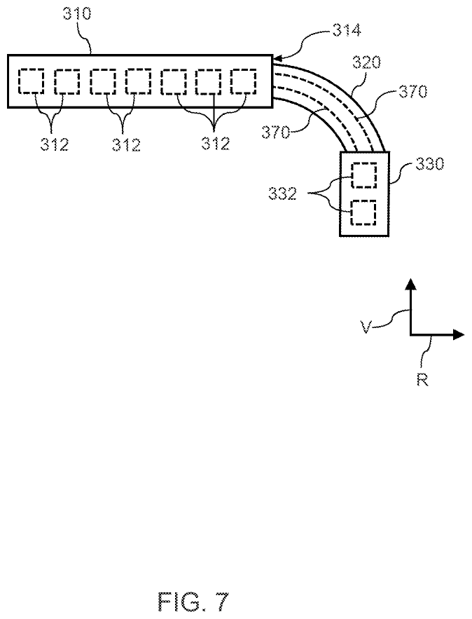

Referring now to FIGS. 6 and 7, a display 300 for a wearable computing device is provided according to some implementations of the present disclosure. In some implementations, the display 300 can define a circumferential direction C, a radial direction R, and a vertical direction V. The display 300 can be implemented in wearable computing devices that include a three-dimensional cover. For example, the display 300 can be used in a wearable computing device that includes the three-dimensional cover 200 depicted in FIGS. 4 and 5.

As shown, the display 300 includes a first display area 310 (e.g., main display) having a first plurality of pixels 312. For instance, the first plurality of pixels 312 can include a total number of pixels needed to cover a substantial portion (e.g., greater than 90 percent) of the first display area 310. The first display area 310 can display content for viewing by a user of the wearable computing device. Furthermore, the first display area 310 can have a substantially annular (e.g., circular) shape. In some implementations, the first display area 310 can be substantially flat.

The display 300 can include a connecting area 320. In some implementations, the connecting area 320 can be void of any pixels. In this manner, the connecting area 320 cannot display content. As shown, the connecting area 320 extends from a periphery 314 of the first display area 310. For instance, the connecting area 320 can extend outwardly from the periphery 314 of the first display area 310 along the radial direction R. Furthermore, in some implementations, the connecting area 320 can be curved. For example, the connecting area 320 can extend from the periphery 314 of the first display area 310 along the radial direction R and the vertical direction V.

The display 300 includes a second display area 330 (e.g., sub-display) having a second plurality of pixels 332. In this manner, the second display area 330 can display content for viewing by the user of the wearable computing device. In some implementations, the second plurality of pixels 332 can include a total number of pixels needed to cover a substantial portion (e.g., greater than 90 percent) of the second display area 330. As shown, the second plurality of pixels 332 can, in some implementations, be arranged in a plurality of rows. Furthermore, the pixels included in each of the plurality of rows can be spaced apart from one another along the circumferential direction C. In this manner, the second display area 330 can display content for viewing by the user of the wearable computing device.

In some implementations, the second display area 330 can be configured as an always-on display. Alternatively or additionally, the second display area 330 can be configured as a touch-screen display. For instance, the second display area 330 can include one or more touch sensors. In this manner, the user can provide user-input (e.g., touch, scroll, etc.) via the second display area 330.

As shown, the second display area 330 can extend from the connecting area 320. In this manner, the first display area 310 and the second display area 330 can be formed in one piece via the connecting area 320. The second display area 330 can include a first portion 334 and a second portion 336. As shown, the first portion 334 of the second display area 330 can extend from the connecting area 320 in a first direction D1 (e.g., counterclockwise) to a distal end 335. Additionally, the second portion 336 of the second display area 330 can extend from the connecting area 320 in a second direction D2 (e.g., clockwise) to a distal end 337. It should be understood that the second direction D2 is opposite the first direction D1. In this manner, the first portion 334 of the second display area 330 can extend around a first portion (e.g., first half) of a periphery 314 of the first display area 310, and the second portion 336 of the second display area 330 can extend around a second portion (e.g., second half) of the periphery 314 of the first display area 310.

It should be understood that the first portion of the periphery 314 of the first display area 310 is different from the second portion of the periphery 314 of the first display area 310. In this manner, the first portion 334 of the second display area 330 and the second portion 336 of the second display area 330 do not overlap one another. For instance, the distal end 335 of the first portion 334 of the second display area 330 does not extend beyond the distal end 337 of the second portion 336 of the second display area 330 along the circumferential direction C.

In some implementations, a first gap 350 is defined between the periphery 314 of the first display area 310 and the first portion 334 of the second display area 330. Additionally, a second gap 352 is defined between the periphery 314 of the first display area 310 and the second portion 336 of the second display area 330.

In some implementations, the first portion 334 of the second display area 330 and the second portion 336 of the second display area 330 can be spaced apart from one another such that a gap 340 is defined between the distal end 335 of the first portion 334 of the second display area 330 and the distal end 337 of the second portion 336 of the second display area 330. For example, the gap 340 can be defined along the circumferential direction C between the distal end 335 of the first portion 334 of the second display area 330 and the distal end 337 of the second portion 336 of the second display area 330. In alternative implementations, the distal end 335 of the first portion 334 can contact (e.g. touch) the distal end 337 of the second portion 336 such that there is no gap defined therebetween.

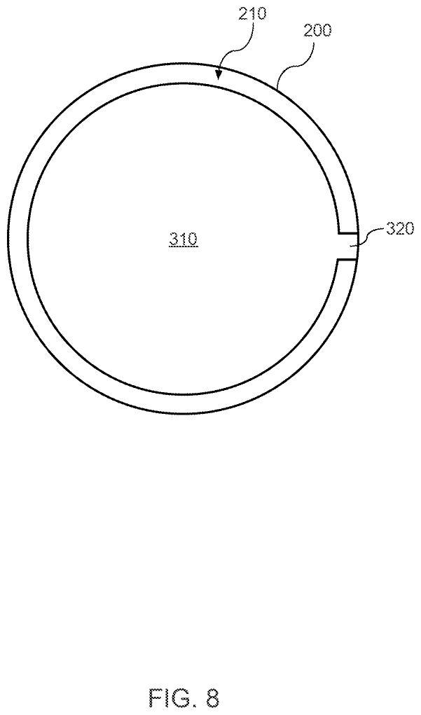

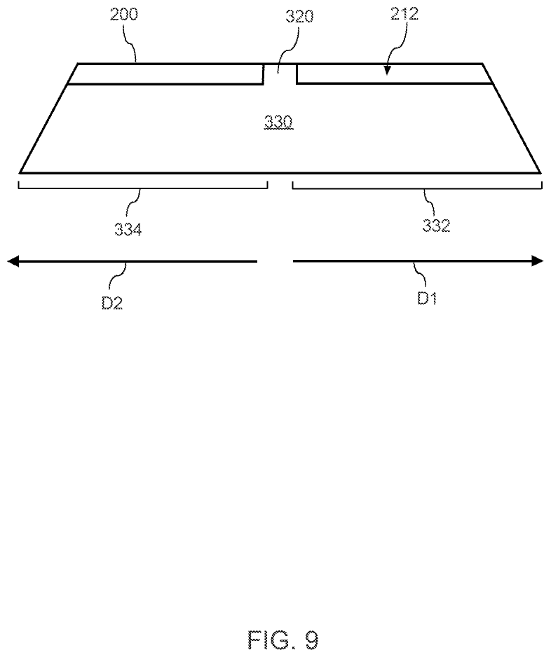

Referring now to FIGS. 8 and 9, the display 300 (FIG. 6) can be positioned within the internal volume 230 (FIG. 4) defined by the three-dimensional cover 200. For instance, the first display area 310 of the display 300 can be viewed through the first portion 210 (e.g., flat portion) of the three-dimensional cover 200. Additionally, the second display area 330 can be viewed through the second portion 212 (e.g., curved portion) of the three-dimensional cover 200. In this manner, the display 300 can be visible through the first portion 210 (e.g., flat portion) of the three-dimensional cover 200 and the second portion 212 (e.g., curved portion) of the three-dimensional cover 200. In some implementations, the second display area 330 can have a conical shape.

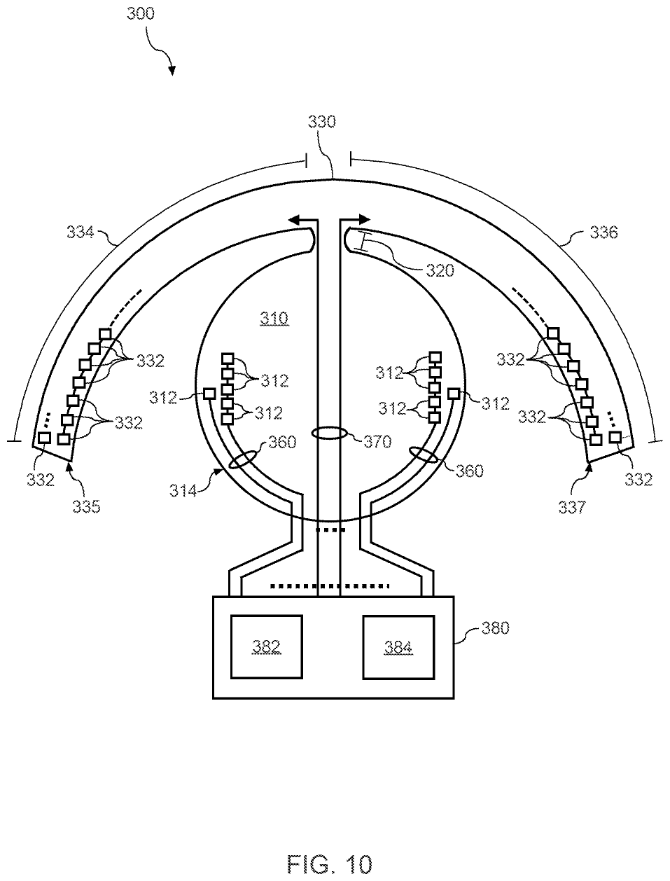

Referring now to FIG. 10, the display 300 is depicted in an unmounted condition in which all display areas (e.g., first display area 310, second display area 330) are arranged flat in the same plane. As shown, the display 300 can include a first plurality of conductors 360 associated with the first display area 310. For instance, each of the first plurality of conductors 360 can be electrically coupled to a corresponding pixel of the first plurality of pixels 312. In some implementations, multiple conductors of the first plurality of conductors can be electrically coupled to each of the first plurality of pixels 312. In such implementations, a first conductor of the first plurality of conductors 360 can be coupled to a first pixel of the first plurality of pixels 312 and can be used as a data line. In this manner, data can be written to the first pixel of the first plurality of pixels 312 via the first conductor of the first plurality of conductors 360. Additionally, a second conductor of the first plurality of conductors 360 can be electrically coupled to the first pixel and can be used as a scan line. In this manner, electrical signals associated with resetting the first pixel can be provided via the second conductor of the first plurality of conductors 360.

As shown, the display 300 can include a second plurality of conductors 370. The second plurality of conductors 370 can be electrically coupled to a corresponding pixel of the second plurality of pixels 332. It should be understood that the second plurality of conductors 370 can function in the same manner as the first plurality of conductors 360 discussed above with reference to the first display area 310 of the display 300. Furthermore, the second plurality of conductors 370 can extend to the second display area 330 via the connecting area 320 of the display 300.

The display 300 can include a display driver circuit 380. As shown, the display driver circuit 380 can be electrically coupled to each of the first plurality of pixels 312 via a corresponding conductor of the first plurality of conductors 360. Additionally, the display driver circuit 380 can be electrically coupled to each of the second plurality of pixels 332 via a corresponding conductor of the second plurality of conductors 370. In this manner, the display driver circuit 380 can control operation of the first display area 310 (e.g., first plurality of pixels 312) and the second display area (e.g., second plurality of pixels 332).

In some implementations, the display driver circuit 380 can include a first memory buffer 382 and a second memory buffer 384. The first memory buffer 382 can store content to be displayed via the first display area 310 of the display 300. Additionally, the second memory buffer 384 can store content to be displayed via the second display area 330 of the display 300. In this manner, the display driver circuit 380 can independently control the first display area 310 of the display 300 and the second display area 330 of the display 300. For instance, the display driver circuit 380 can control operation of the first display area 310 to display first content stored in the first memory buffer 382. Additionally, the display driver circuit 380 can control operation of the second display area 330 to display second content stored in the second memory buffer 384. In some implementations, the second content can be different than the first content.

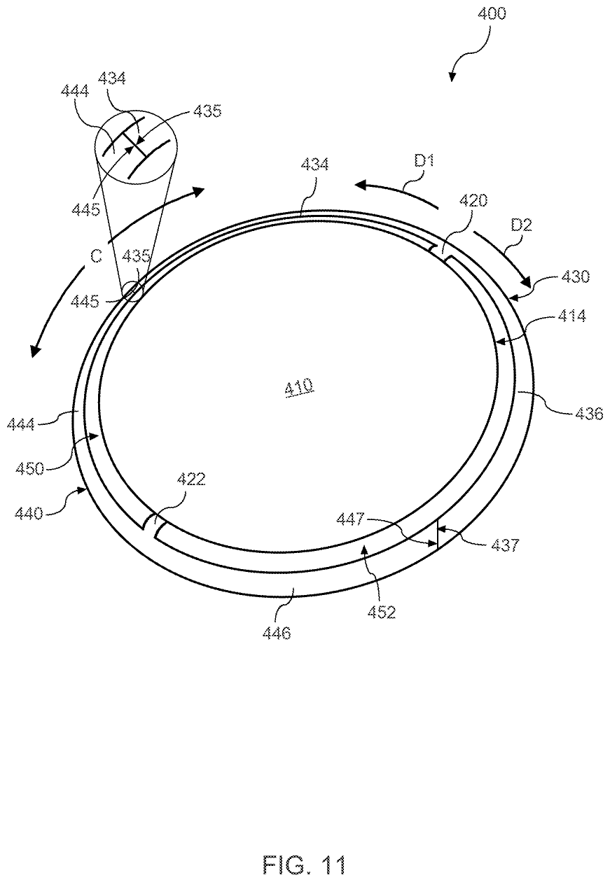

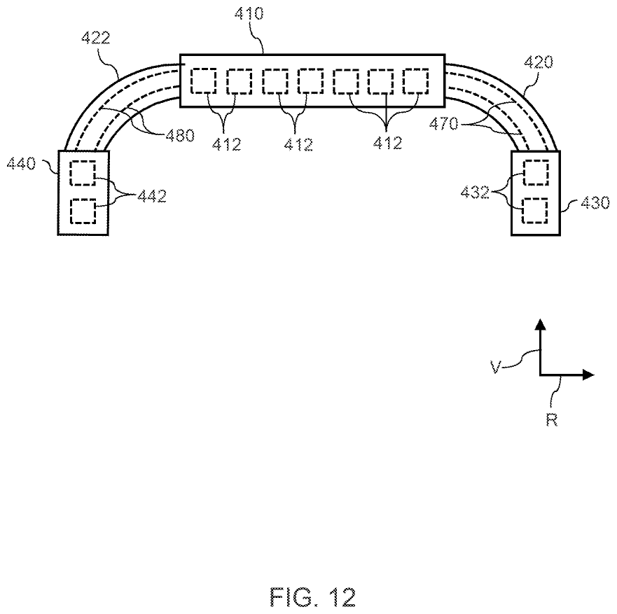

Referring now to FIGS. 11 and 12, another display 400 for a wearable device having a three-dimensional cover is provided according to some implementations of the present disclosure. The display 400 can define a circumferential direction C, a radial direction R, and a vertical direction V. The display 400 can be implemented in wearable computing devices that include a three-dimensional cover. For example, the display 400 can be used in a wearable computing device that includes the three-dimensional cover 200 depicted in FIGS. 4 and 5.

As shown, the display 400 includes a first display area 410 (e.g., main display) having a first plurality of pixels 412. For instance the first plurality of pixels 412 can include a total number of pixels needed to cover a substantial portion (e.g., greater than 90 percent) of the first display area 410. The first display area 410 can display content for viewing by a user of the wearable computing device. Furthermore, the first display area 410 can have a substantially annular shape.

The display 400 can include a first connecting area 420. It should be understood that the first connecting area 420 does not include any pixels. As shown, the first connecting area 420 extends from the first display area 410 along the radial direction R. Furthermore, in some implementations, the first connecting area 420 can be curved. In such implementations, the first connecting area 420 can extend from the first display area 410 along the radial direction R and the vertical direction V.

The display 400 includes a second display area 430 (e.g., first sub-display) having a second plurality of pixels 432. In this manner, the second display area 430 can display content for viewing by the user of the wearable computing device. In some implementations, the second plurality of pixels 432 can include a total number of pixels needed to cover a substantial portion (e.g., greater than 90 percent) of the second display area 430. As shown, the second plurality of pixels 432 can, in some implementations, be arranged in a plurality of rows. Furthermore, the pixels included in each of the plurality of rows can be spaced apart from one another along the circumferential direction C. In this manner, the second display area 430 can display content for viewing by the user of the wearable computing device. In some implementations, the second display area 430 can be configured as an always-on display.

The second display area 430 can extend from the first connecting area 420. In this manner, the second display area 430 can be spaced apart from the first display area 410 along the radial direction R. Furthermore, in implementations in which the first connecting area 420 is curved or bent, the second display area 430 can be spaced apart from the first display area 410 along the radial direction R and the vertical direction V.

The second display area 430 can include a first portion 434 and a second portion 436. As shown, the first portion 434 of the second display area 430 can extend from the first connecting area 420 along the circumferential direction C in a first direction (e.g., counterclockwise) to a distal end 435. Additionally, the second portion 436 of the second display area 430 can extend from the first connecting area 420 along the circumferential direction C in a second direction D2 (e.g., clockwise) to a distal end 437. It should be understood that the second direction D2 is opposite the first direction D1. In this manner, the first portion 434 of the second display area 430 can extend around a first portion (e.g., first quarter) of a periphery 414 of the first display area 410 and the second portion 436 of the second display area 430 can extend around a second portion (e.g., second quarter) of the periphery 414 of the first display area 410. It should be understood that the first portion of the periphery 414 of the first display area 410 is different than the second portion of the periphery 414 of the first display area 410. In this manner, the first portion 434 of the second display area 430 and the second portion 436 of the second display area 430 do not overlap.

The display 400 can include a second connecting area 422. It should be understood that the second connecting area 422 does not include any pixels. As shown, the second connecting area 422 is spaced apart from the first connecting area 420 along the circumferential direction C and extends from the first display area 410 along the radial direction R. In this manner, the first connecting area 420 and the second connecting area 422 are spaced apart from one another along the periphery 414 of the first display area 400. Furthermore, in some implementations, the second connecting area 422 can be curved. In such implementations, the second connecting area 422 can extend from the first display area 410 along the radial direction R and the vertical direction V

The display 400 includes a third display area 440 (e.g., second sub-display) having a third plurality of pixels 442. In this manner, the third display area 440 can display content for viewing by the user of the wearable computing device. In some implementations, the third plurality of pixels 442 can include a total number of pixels needed to cover a substantial portion (e.g., greater than 90 percent) of the third display area 440. As shown, the third plurality of pixels 442 can, in some implementations, be arranged in a plurality of rows. Furthermore, the pixels included in each of the plurality of rows can be spaced apart from one another along the circumferential direction C. In this manner, the third display area 440 can display content for viewing by the user of the wearable computing device. In some implementations, the third display area 440 can be configured as an always-on display. Alternatively, or additionally, the third display area 440 can be configured as a touch-screen display.

The third display area 440 can extend from the second connecting area 422. In this manner, the third display area 440 can be spaced apart from the first display area 410 along the radial direction R. Furthermore, in implementations in which the second connecting area 422 is curved or bent, the third display area 440 can be spaced apart from the first display area 410 along the radial direction R and the vertical direction V.

The third display area 440 can include a first portion 444 and a second portion 446. As shown, the first portion 444 of the third display area 440 can extend from the second connecting area 422 along the circumferential direction C in the second direction D2 (e.g., clockwise) to a distal end 445. Additionally, the second portion 446 of the third display area 440 can extend from the second connecting area 422 along the circumferential direction C in the first direction D1 (e.g., counterclockwise) to a distal end 447.

It should be understood that the second direction D2 is opposite the first direction D1. In this manner, the first portion 444 of the third display area 440 can extend around a third portion (e.g., third quarter) of the periphery 414 of the first display area 410 and the second portion 446 of the third display area 440 can extend around a fourth portion (e.g., fourth quarter) of the periphery 414 of the first display area 410. It should be understood that the third portion of the periphery 414 of the first display area 410 is different from the fourth portion of the periphery 414 of the first display area 410. In this manner, the first portion 444 of the third display area 440 and the second portion 446 of the third display area 440 do not overlap. Additionally, the third portion of the periphery 414 of the first display area 410 and the fourth portion of the periphery 414 of the first display area 410 can be different than the first portion of the periphery 414 of the first display area 410 and the second portion of the periphery 414 of the first display area 410. In this manner, the first portion 444 of the third display area 440 and the first portion 434 of the second display area 430 do not overlap one another. Additionally, the second portion 446 of the third display area 440 and the second portion 436 of the second display area 430 do not overlap one another.

In some implementations, the distal end 435 of the first portion 434 of the second display area 430 and the distal end 445 of the first portion 444 of the third display area 440 can contact (e.g., touch). In such implementations, there is no gap between the distal end 435 of the first portion 434 of the second display area 430 and the distal end 445 of the first portion 444 of the third display area 440. In alternative implementations, a gap can be defined between the distal end 435 of the first portion 434 of the second display area 430 and the distal end 445 of the first portion 444 of the third display area 440.

In some implementations, the distal end 437 of the second portion 436 of the second display area 430 and the distal end 445 of the second portion 446 of the third display area 440 can contact (e.g., touch). In this manner, there is no gap between the distal end 437 of the second portion 436 of the second display area 430 and the distal end 447 of the second portion 446 of the third display area 440. In alternative implementations, a gap can be defined between the distal end 437 of the second portion 436 of the second display area 430 and the distal end 447 of the second portion 446 of the third display area 440.

In some implementations, a first gap 450 is defined between the periphery 414 of the first display area 410 and the first portion 434 of the second display area 330. Additionally, the first gap 450 can be further defined between the periphery 414 of the first display area 410 and the first portion 444 of the third display area 440. Furthermore, in some implementations, a second gap 452 can be defined between the periphery 414 of the first display area 410 and the second portion 436 of the second display area 430. Additionally, the second gap 452 can be further defined between the periphery 414 of the first display area 410 and the second portion 446 of the third display area 440

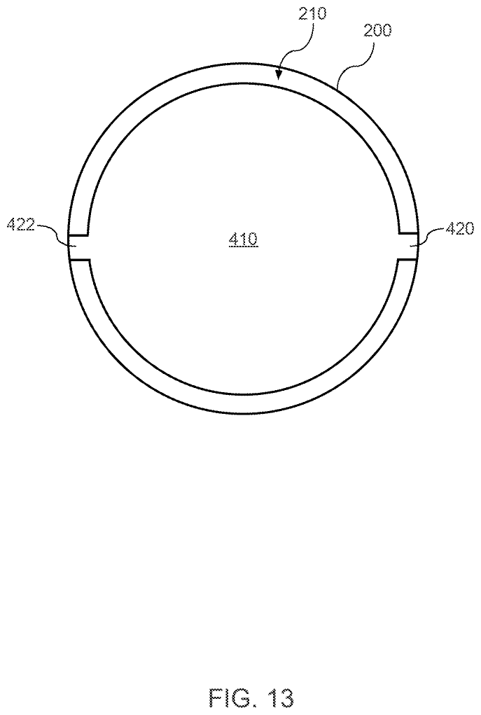

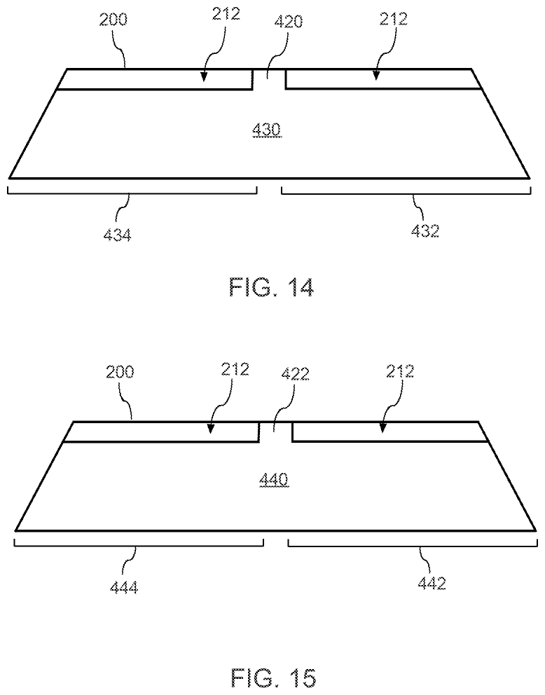

Referring now to FIGS. 13 through 15, the display 400 (FIG. 11) can be positioned within the internal volume 230 (FIG. 4) defined by the three-dimensional cover 200. For instance, the first display area 410 of the display 400 can be viewed through the first portion 210 (e.g., flat portion) of the three-dimensional cover 200. Additionally, the second display area 430 and the third display area 440 can be viewed through the second portion 214 (e.g., curved portion) of the three-dimensional cover 200. In this manner, the display 400 can be visible through the first portion 210 (e.g., flat portion) of the three-dimensional cover 200 and the second portion 212 (e.g., curved portion) of the three-dimensional cover 200.

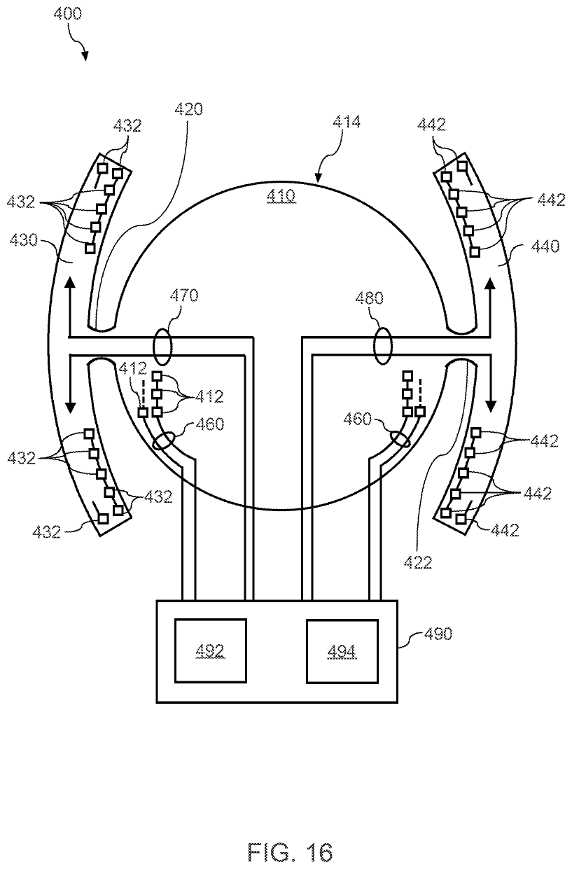

Referring now to FIG. 16, the display 400 is depicted in an unmounted condition in which all display areas (e.g., first display area 410, second display area 430, third display area 440) are arranged flat in the same plane the display 400. As shown, the display 400 can include a first plurality of conductors 460 associated with the first display area 410. For instance, each of the first plurality of conductors 460 can be electrically coupled to a corresponding pixel of the first plurality of pixels 412. In some implementations, multiple conductors of the first plurality of conductors can be electrically coupled to each of the first plurality of pixels 412. In such implementations, a first conductor of the first plurality of conductors 460 can be coupled to a first pixel of the first plurality of pixels 412 and can be used as a data line. In this manner, data can be written to the first pixel of the first plurality of pixels 412 via the first conductor of the first plurality of conductors 460. Additionally, a second conductor of the first plurality of conductors 360 can be electrically coupled to the first pixel and can be used as a scan line. In this manner, electrical signals associated with resetting the first pixel can be provided via the second conductor.

As shown, the display 400 can include a second plurality of conductors 470. The second plurality of conductors 470 can be electrically coupled to a corresponding pixel of the second plurality of pixels 432 of the second display area 430. It should be understood that the second plurality of conductors 470 can function in the same manner as the first plurality of conductors 460 discussed above with reference to the first display area 410 of the display 400. Furthermore, the second plurality of conductors 470 can extend to the second display area 430 via the first connecting area 420 of the display 400.

The display 400 can further include a third plurality of conductors 480. The third plurality of conductors 480 can be electrically coupled to a corresponding pixel of the third plurality of pixels 442 of the third display area 440. It should be understood that the third plurality of conductors 480 can function in the same manner as the first plurality of conductors 460 discussed above with reference to the first display area 410 of the display 400. Furthermore, the third plurality of conductors 480 can extend to the third display area 440 via the second connecting area 422 of the display 400

The display 400 can include a display driver circuit 490. As shown, the display driver circuit 490 can be electrically coupled to each of the display areas (e.g., first display area 410, second display area 430, third display area 440) via corresponding conductors of the plurality of conductors 460, 470, 480. For instance, the display driver circuit 490 can be electrically coupled to each of the first plurality of pixels 412 of the first display area 410 via a corresponding conductor of the first plurality of conductors 460. The display driver circuit 490 can be electrically coupled to each of the second plurality of pixels 432 of the second display area 430 via a corresponding conductor of the second plurality of conductors 470. The display driver circuit 490 can be electrically coupled to each of the third plurality of pixels 442 of the third display area 440 via a corresponding conductor of the third plurality of conductors 480. In this manner, the display driver circuit 380 can control operation of the first display area 410 (e.g., first plurality of pixels 412), the second display area (e.g., second plurality of pixels 432), and the third display area 440 (e.g., third plurality of pixels 442).

In some implementations, the display driver circuit 490 can include a first memory buffer 492 and a second memory buffer 494. The first memory buffer 492 can store content to be displayed via the first display area 410 of the display 300. The second memory buffer 3494 can store content to be displayed via the second display area 430 of the display 400 and the third display area 440 of the display 400. In this manner, the display driver circuit 490 can independently control the first display area 410 of the display 300 and the second and third display areas 430, 440 of the display 400. For instance, the display driver circuit 490 can control operation of the first display area 410 to display first content stored in the first memory buffer 492. Additionally, the display driver circuit 490 can control operation of the second and third display areas 430, 440 to display second content stored in the second memory buffer 494.

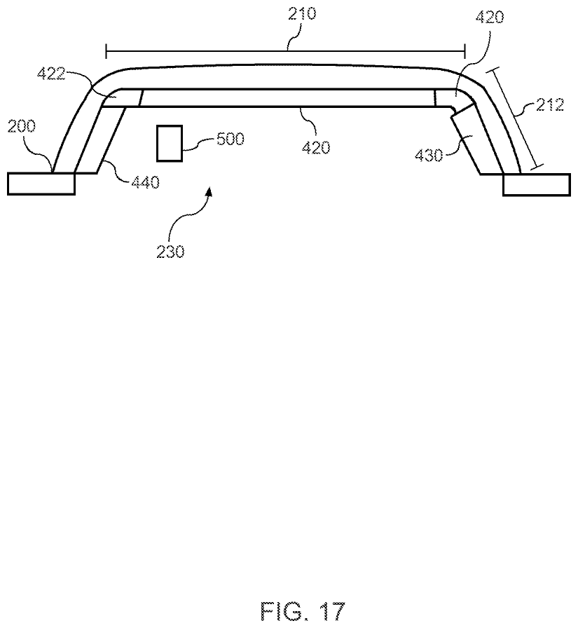

Referring now to FIG. 17, an image sensor 500 (e.g., camera) of a wearable computing device can be positioned within the internal volume 230 of the three-dimensional cover 200. More particularly, the image sensor 500 can be positioned behind the sub-display area (e.g., second display area 430, third display area 440) of the display 400 (FIG. 11). In this manner, a field of view of the image sensor 500 can be widened compared to a field of view of an image sensor positioned behind the main display area (e.g., first display area 410) of the display 400 due, at least in part, to the sub-display area being coupled (e.g., laminated) to the second portion 212 (e.g., curved portion) of the three-dimensional cover 200.

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, and equivalents to such embodiments. Accordingly, the subject disclosure does not preclude inclusion of such modifications, variations and/or additions to the present subject matter as would be readily apparent to one of ordinary skill in the art. For instance, features illustrated or described as part of one embodiment can be used with another embodiment to yield a still further embodiment. Thus, it is intended that the present disclosure cover such alterations, variations, and equivalents.

1. A display comprising:
a first display area having a first plurality of pixels;
a connecting area extending from a periphery of the first display area; and
a second display area having a second plurality of pixels, the second display area comprising a first portion and a second portion, the first portion extending from the connecting area and around a first portion of the periphery of the first display area, the second portion extending from the connecting area and around a second portion of the periphery of the first display area, the second portion of the periphery being different than the first portion of the periphery.

2. The display of claim 1, wherein a total number of pixels included in the first plurality of pixels is different than a total number of pixels included in the second plurality of pixels.

3. The display of claim 1, wherein:
a first gap is defined between the first portion of the second display area and the first portion of the periphery of the first display area; and
a second gap is defined between the second portion of the second display area and the second portion of the periphery of the first display area.

4. The display of claim 1, further comprising:
a first plurality of conductors, each conductor of the first plurality of conductors electrically coupled to a corresponding pixel of the first plurality of pixels; and
a second plurality of conductors, each conductor of the second plurality of conductors electrically coupled to a corresponding pixel of the second plurality of pixels.

5. The display of claim 4, wherein each conductor of the second plurality of conductors extends from the first display area to the second display area via the connecting area.

6. The display of claim 1, further comprising:
a display driver circuit comprising a first memory buffer and a second memory buffer, the first memory buffer communicatively coupled to each of the first plurality of pixels via a corresponding conductor of the first plurality of conductors, the second memory buffer communicatively coupled to each of the second plurality of pixels via a corresponding conductor of the second plurality of conductors.

7. The display of claim 1, wherein a gap is defined between an end of the first portion of the second display area and an end of the second portion of the second display area.

8. A wearable computing device comprising:
a housing;
a three-dimensional cover positioned on the housing, the three-dimensional cover comprising a transparent material, the three-dimensional cover defining an internal volume; and
a display disposed within the internal volume defined by the three-dimensional cover, the display comprising:
a first display area having a first plurality of pixels;
a first connecting area extending from a periphery of the first display area; and
a second display area having a second plurality of pixels, the second display area comprising a first portion and a second portion, the first portion extending from the first connecting area and around a first portion of the periphery of the first display area, the second portion extending from the first connecting area and around a second portion of the periphery of the first display area, the second portion of the periphery of the first display area being different than the first portion of the periphery of the first display area.

9. The wearable computing device of claim 8, wherein the first portion of the second display area and the second portion of the second display area are each coupled to a curved portion of an interior surface of the three-dimensional cover.

10. The wearable computing device of claim 8, wherein at least one of the first portion of the second display area or the second portion of the second display area is laminated to the curved portion of the interior surface of the three-dimensional cover.

11. The wearable computing device of claim 9, wherein the display comprises an organic light emitting diode (OLED) display.

12. The wearable computing device of claim 8, wherein:
a first gap is defined between the first display area and the first portion of the second display area; and
a second gap is defined between the first display area and the second portion of the second display area.

13. The wearable computing device of claim 8, wherein the display further comprises:
a second connecting area extending from the periphery of the first display area, the second connecting area spaced apart from the first connecting area along the periphery of the first display area; and
a third display area having a third plurality of pixels, the third display area comprising a first portion extending from the second connecting area and around a third portion of the periphery of the first display area, the third display area further comprising a second portion extending from the second connecting area and around a fourth portion of the periphery of the first display area.

14. The wearable computing device of claim 8, wherein the display further comprises:
a first plurality of conductors, each conductor of the first plurality of conductors electrically coupled to a corresponding pixel of the first plurality of pixels; and
a second plurality of conductors, each conductor of the second plurality of conductors electrically coupled to a corresponding pixel of the second plurality of pixels.

15. The wearable computing device of claim 14, wherein
each conductor of the second plurality of conductors extends from the first display area to the second display area via the first connecting area.

16. The wearable computing device of claim 8, wherein the display further comprises:
a display driver circuit comprising a first memory buffer and a second memory buffer, the first memory buffer communicatively coupled to each of the first plurality of pixels via a corresponding conductor of the first plurality of conductors, the second memory buffer communicatively coupled to each of the second plurality of pixels via a corresponding conductor of the second plurality of conductors.

17. The wearable computing device of claim 8, wherein the second display area is configured as a touch-screen display.

18. The wearable computing device of claim 8, wherein the transparent material comprises a glass material.

19. The wearable computing device of claim 8, further comprising:
an image sensor positioned within the internal volume of the three-dimensional cover such that the image sensor is positioned behind the second display area of the display.
